(19) United States
(12) Patent Application Publication
(10) Pub. No.: US 2025/0192750 A1
(43) Pub. Date: Jun. 12, 2025

(54) BULK ACOUSTIC WAVE DEVICE WITH BONDING LAYER FOR FREQUENCY ADJUSTMENT LAYER

(71) Applicant: Skyworks Solutions, Inc., Irvine, CA (US)

(72) Inventors: Yasuhiro Yamauchi, Osaka-Shi (JP); Jun Hashimoto, Osaka-Shi (JP); Hiroyuki Tahara, Osaka-Shi (JP)

(21) Appl. No.: 18/965,163

(22) Filed: Dec. 2, 2024

Related U.S. Application Data
(60) Provisional application No. 63/608,992, filed on Dec. 12, 2023.
(60) Provisional application No. 63/608,977, filed on Dec. 12, 2023.

(51) Int. Cl. H03H 9/13; H03H 3/04; H03H 9/17

(52) U.S. Cl. CPC H03H 9/131; H03H 3/04; H03H 9/173; H03H 9/174; H03H 9/175; H03H 2003/0428

(57) ABSTRACT

A bulk acoustic wave device and a method of forming the same is disclosed. The bulk acoustic wave device can include a piezoelectric layer positioned between a first electrode and a second electrode. The bulk acoustic wave device can include a frequency adjustment layer over the second electrode. The bulk acoustic wave device can include a bonding layer between the second electrode and the frequency adjustment layer. A bonding strength between the second electrode and the frequency adjustment layer with the bonding layer is greater than a bonding strength between the second electrode and the frequency adjustment layer without the bonding layer. The bonding layer can have a thickness in a range between 1 nanometer and 20 nanometers.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/608,992, filed Dec. 12, 2023, titled “BULK ACOUSTIC WAVE DEVICE WITH BONDING LAYER FOR FREQUENCY ADJUSTMENT LAYER,” and U.S. Provisional Patent Application No. 63/608,977, filed Dec. 12, 2023, titled “BULK ACOUSTIC WAVE DEVICE WITH BONDING LAYER FOR FREQUENCY ADJUSTMENT LAYER,” are hereby incorporated by reference under 37 CFR 1.57 in their entirety.

### BACKGROUND

### Technical Field

Embodiments of this disclosure relate to acoustic wave devices, and in particular, to bulk acoustic wave devices with a bonding layer.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed. A bulk acoustic wave resonator can include a set of metal electrodes deposited on opposite surfaces of a piezoelectric material, generating a bulk acoustic wave within the volume of the piezoelectric material. The interaction between the electrodes and the piezoelectric material results in the formation and propagation of a bulk acoustic wave.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a bulk acoustic wave device including: a piezoelectric layer positioned between a first electrode and a second electrode; a frequency adjustment layer over the second electrode; and a bonding layer between the second electrode and the frequency adjustment layer, a bonding strength between the second electrode and the frequency adjustment layer with the bonding layer being greater than a bonding strength between the second electrode and the frequency adjustment layer without the bonding layer.

In some embodiments, the techniques described herein relate to a bulk acoustic wave device wherein the bonding layer has a thickness in a range between 1 nanometer and 20 nanometers.

In some embodiments, the techniques described herein relate to a bulk acoustic wave device wherein the bonding layer includes a piezoelectric material.

In some embodiments, the techniques described herein relate to a bulk acoustic wave device wherein the bonding layer includes aluminum nitride.

In some embodiments, the techniques described herein relate to a bulk acoustic wave device wherein the bonding layer includes a doped piezoelectric material.

In some embodiments, the techniques described herein relate to a bulk acoustic wave device wherein the bonding layer includes scandium doped aluminum nitride or scandium doped zinc oxide.

In some embodiments, the techniques described herein relate to a bulk acoustic wave device wherein the bonding layer includes a material of the piezoelectric layer.

In some embodiments, the techniques described herein relate to a bulk acoustic wave device wherein the second electrode includes ruthenium.

In some embodiments, the techniques described herein relate to a bulk acoustic wave device further including a support structure, the first electrode positioned between the support structure and the piezoelectric layer.

In some embodiments, the techniques described herein relate to a bulk acoustic wave device wherein the support structure includes an acoustic mirror.

In some embodiments, the techniques described herein relate to a bulk acoustic wave device is a film acoustic wave resonator.

In some embodiments, the techniques described herein relate to a bulk acoustic wave device wherein the first and second electrodes include the same material.

In some embodiments, the techniques described herein relate to a bulk acoustic wave device wherein the second electrode includes molybdenum (Mo), tungsten (W), ruthenium (Ru), chromium (Cr), iridium (Ir), or platinum (Pt).

In some aspects, the techniques described herein relate to a bulk acoustic wave device including: a piezoelectric layer positioned between a first electrode and a second electrode; a bonding layer over the second electrode; and a frequency adjustment layer over the bonding layer, the bonding layer having a thickness in a range between 1 nanometer and 20 nanometers, and the frequency adjustment layer being in contact with the bonding layer.

In some embodiments, the techniques described herein relate to a bulk acoustic wave device wherein the thickness of the bonding layer is in a range between 1 nanometer and 10 nanometers.

In some embodiments, the techniques described herein relate to a bulk acoustic wave device wherein a bonding strength between the second electrode and the frequency adjustment layer with the bonding layer being greater than a bonding strength between the second electrode and the frequency adjustment layer without the bonding layer.

In some embodiments, the techniques described herein relate to a bulk acoustic wave device wherein the bonding layer includes a piezoelectric material.

In some embodiments, the techniques described herein relate to a bulk acoustic wave device wherein the second electrode includes molybdenum (Mo), tungsten (W), ruthenium (Ru), chromium (Cr), iridium (Ir), or platinum (Pt).

In some aspects, the techniques described herein relate to a method of forming a bulk acoustic wave device, the method including: forming a stack of a first electrode, a second electrode, and a piezoelectric layer positioned between the first electrode and the second electrode; depositing a bonding layer over the second electrode; and providing a frequency adjustment layer on the bonding layer, a bonding strength between the second electrode and the frequency adjustment layer with the bonding layer being greater than a bonding strength between the second electrode and the frequency adjustment layer without the bonding layer.

In some embodiments, the techniques described herein relate to a method further including removing organic matter and oxide from a surface of the second electrode thereby forming a treated surface, the bonding layer is provided on the treated surface.

In some aspects, the techniques described herein relate to a bulk acoustic wave device including: a piezoelectric layer positioned between a first electrode and a second electrode; a frequency adjustment layer over the second electrode; and a bonding layer between the second electrode and the frequency adjustment layer, a mass density of the bonding layer being less than a mass density of the second electrode.

In some embodiments, the techniques described herein relate to a bulk acoustic wave device wherein the bonding layer and the piezoelectric layer include the same material.

In some embodiments, the techniques described herein relate to a bulk acoustic wave device wherein the bonding layer includes aluminum nitride or zinc oxide.

In some embodiments, the techniques described herein relate to a bulk acoustic wave device wherein the bonding layer includes a doped piezoelectric material.

In some embodiments, the techniques described herein relate to a bulk acoustic wave device wherein the bonding layer includes scandium doped aluminum nitride or scandium doped zinc oxide.

In some embodiments, the techniques described herein relate to a bulk acoustic wave device wherein the first electrode and the second electrode include different materials, the bonding layer includes a material of the first electrode.

In some embodiments, the techniques described herein relate to a bulk acoustic wave device further including a support structure, the first electrode positioned between the support structure and the piezoelectric layer.

In some embodiments, the techniques described herein relate to a bulk acoustic wave device wherein the bonding layer includes a material of a layer in the support structure.

In some embodiments, the techniques described herein relate to a bulk acoustic wave device wherein the support structure includes an acoustic mirror.

In some embodiments, the techniques described herein relate to a bulk acoustic wave device is a film acoustic wave resonator.

In some embodiments, the techniques described herein relate to a bulk acoustic wave device wherein the second electrode includes molybdenum (Mo), tungsten (W), ruthenium (Ru), chromium (Cr), iridium (Ir), or platinum (Pt).

In some aspects, the techniques described herein relate to a bulk acoustic wave device including: a piezoelectric layer positioned between a first electrode and a second electrode; a frequency adjustment layer over the second electrode; and a bonding layer between the second electrode and the frequency adjustment layer, the bonding layer including a piezoelectric material.

In some embodiments, the techniques described herein relate to a bulk acoustic wave device wherein the bonding layer and the piezoelectric layer include the same material.

In some embodiments, the techniques described herein relate to a bulk acoustic wave device wherein the bonding layer includes aluminum nitride or zinc oxide.

In some embodiments, the techniques described herein relate to a bulk acoustic wave device further including a support structure, the first electrode positioned between the support structure and the piezoelectric layer.

In some embodiments, the techniques described herein relate to a bulk acoustic wave device wherein the support structure includes an acoustic mirror.

In some embodiments, the techniques described herein relate to a bulk acoustic wave device is a film acoustic wave resonator.

In some embodiments, the techniques described herein relate to a bulk acoustic wave device wherein the second electrode includes molybdenum (Mo), tungsten (W), ruthenium (Ru), chromium (Cr), iridium (Ir), or platinum (Pt).

In some aspects, the techniques described herein relate to a method of forming a bulk acoustic wave device, the method including: forming a stack of a first electrode, a second electrode, and a piezoelectric layer positioned between the first electrode and the second electrode; depositing a bonding layer over the second electrode, a mass density of the bonding layer being less than a mass density of the second electrode; and providing a frequency adjustment layer on the bonding layer.

In some embodiments, the techniques described herein relate to a method wherein the second electrode includes molybdenum (Mo), tungsten (W), ruthenium (Ru), chromium (Cr), iridium (Ir), or platinum (Pt), and the bonding layer includes a piezoelectric material.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a bulk acoustic wave (BAW) device.

FIG. 1B is a schematic cross-sectional side view of the BAW device of FIG. 1A with defects.

FIG. 2 is a schematic cross-sectional side view of a bulk acoustic wave (BAW) device according to an embodiment.

FIG. 3 is a schematic cross-sectional side view of a bulk acoustic wave (BAW) device according to another embodiment.

FIG. 4 is a schematic cross-sectional side view of a bulk acoustic wave (BAW) device according to another embodiment.

FIG. 5 is a flow chart showing a method of forming a BAW device according to an embodiment.

FIG. 6 is a flow chart showing a method of forming a BAW device according to another embodiment.

FIG. 7 is a schematic diagram of an example of an acoustic wave ladder filter.

FIG. 8A is a schematic diagram of an example of a duplexer.

FIG. 8B is a schematic diagram of an example of a multiplexer.

FIG. 9 is a schematic block diagram of a module that includes an antenna switch and duplexers that include one or more bulk acoustic wave devices.

FIG. 10A is a schematic block diagram of a module that includes a power amplifier, a radio frequency switch, and duplexers that include one or more bulk acoustic wave devices.

FIG. 10B is a schematic block diagram of a module that includes a low noise amplifier, a radio frequency switch, and acoustic wave filters that include one or more bulk acoustic wave devices.

FIG. 11 is a schematic block diagram of a module that includes a power amplifier, a radio frequency switch, a duplexer that includes one or more bulk acoustic wave devices.

FIG. 12A is a schematic block diagram of a wireless communication device that includes filters that include one or more bulk acoustic wave devices.

FIG. 12B is a schematic block diagram of another wireless communication device that includes filters that include one or more bulk acoustic wave devices.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Bulk acoustic wave (BAW) devices (e.g., BAW resonators) utilize acoustic waves propagating through a piezoelectric material to achieve specific frequency responses. Frequency adjustment or frequency trimming in a BAW device is a process that enable fine-tuning of a resonant frequency of the device to meet precise specifications or compensate for manufacturing variations. The frequency adjustment or frequency trimming can include modifying an effective acoustic path length within the resonator structure by way of introducing a relatively thin film or layer. For example, a film with a material that can influence the acoustic wave in the BAW device can be provided (e.g., deposited) on an upper electrode of the BAW device. The material, the thickness, and other properties of the film can be modified to fine-tune the resonant frequency of the BAW device. The film can be referred to as a passivation layer in some cases as the film can also function as a passivation layer to protect the BAW device. However, the film may not be adhered to the top electrode with a sufficient bonding strength, and can result in delamination of the film. Therefore, the film may not provide reliable frequency adjustment properties to the BAW device.

In various embodiments disclosed herein, bulk acoustic wave (BAW) devices with a bonding layer that enables reliable frequency adjustment are provided. A BAW device, such as a BAW resonator, can include a first electrode, a second electrode, a piezoelectric layer positioned between the first and second electrodes, a frequency adjustment layer over the second electrode, and a bonding layer between the frequency adjustment layer and the second electrode. A bonding strength between the top electrode and the frequency adjustment layer with the bonding layer is greater than a bonding strength between the top electrode and the frequency adjustment layer without the bonding layer. In some embodiments, the bonding layer can include any piezoelectric material. For example, the bonding layer can include the same material as the piezoelectric layer, aluminum nitride (AlN), zinc oxide (ZnO), or a doped piezoelectric material.

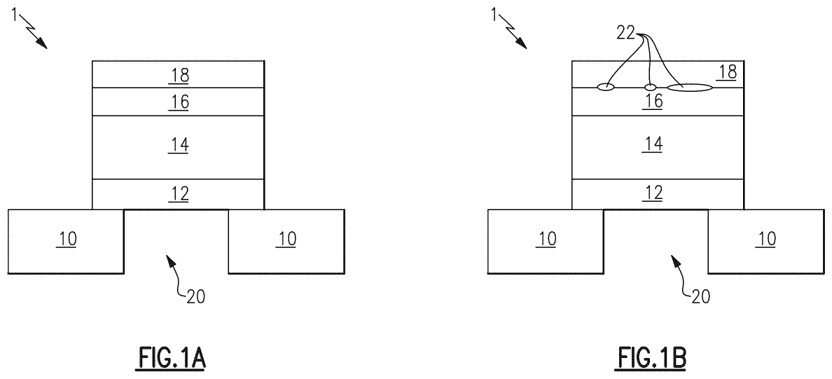

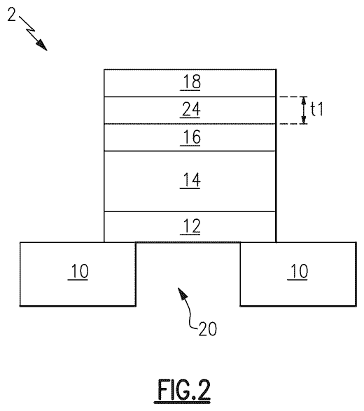

FIG. 1A is a schematic cross-sectional side view of a bulk acoustic wave (BAW) device 1. The BAW device 1 includes a support structure 10, a first electrode 12, a piezoelectric layer 14, a second electrode 16, a frequency adjustment layer 18, and a cavity 20. The cavity 20 can be an air cavity and the BAW device 1 can be a film bulk acoustic wave resonator (FBAR).

A bonding strength between the second electrode 16 and the frequency adjustment layer 18 may not be sufficiently strong to provide a reliable BAW device. When the bonding strength is not sufficiently strong or relatively weak, the frequency adjustment layer 18 can partially or completely delaminate from the second electrode 16 during operation of the BAW device. Such relatively weak bonding can be found more often near an edge of a wafer on which the BAW device is fabricated. Accordingly, devices fabricated at or near the edge may need to be excluded, which lowers manufacturing yield. Especially for high band to ultra-high band (UHB) BAW devices, about 10 mm to about 20 mm from an edge of a wafer may be excluded.

FIG. 1B is a schematic cross-sectional side view of the BAW device 1 with defects 22. The defects 22 can include voids that indicate delamination of the frequency adjustment layer 18 from the second electrode 16. In an effort to mitigate the formation of the defects 22, a surface of the second electrode 16 to which the frequency adjustment layer 18 is disposed can be pre-treated. For example, a surface oxidization process including enhancing roughness by way of oxygen (O₂) ashing can be applied to the surface of the second electrode 16. Another approach to mitigate the formation of the defects 22 is to treat the surface of the second electrode 16 in preparation for forming the frequency adjustment layer 18. Though the surface preparation showed some improvements, they did not provide reliability that satisfies desired specifications.

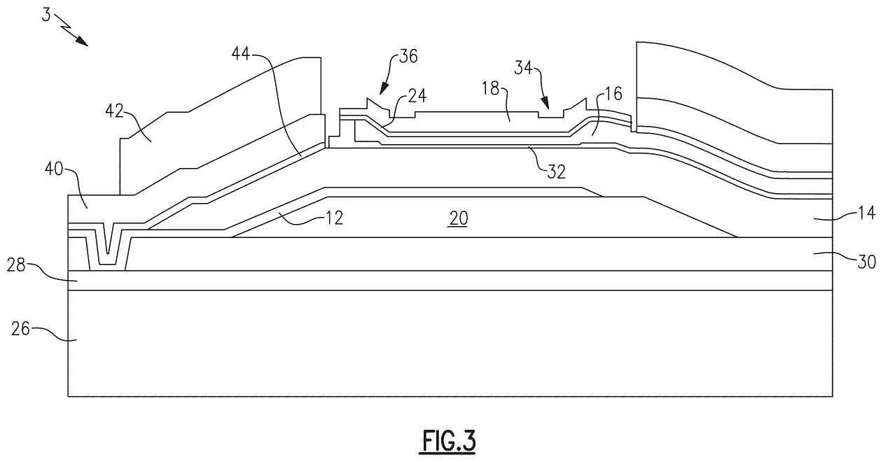

FIG. 2 is a schematic cross-sectional side view of a bulk acoustic wave (BAW) device 2 according to an embodiment. The BAW device 1 includes a support structure 10, a first electrode 12 over the support structure 10, a piezoelectric layer 14 over the first electrode 12, a second electrode 16 over the piezoelectric layer 14, a frequency adjustment layer 18 over the second electrode 16, a bonding layer 24 between the second electrode 16 and the frequency adjustment layer 18, and a cavity 20. The first electrode 12 can be referred to as a bottom or lower electrode, and the second electrode 16 can be referred to as a top or upper electrode.

The support structure 10 can have a multi-layer structure. For example, the support structure 10 can include a support substrate (e.g., a semiconductor substrate such as a silicon substrate), a trap rich layer, a passivation layer, or one or more intermediate layers therebetween. In some embodiments, the cavity 20 can be formed with the support structure 10 or between the support substrate 10 and the first electrode 12. The cavity 20 can be an air cavity and the BAW device 2 can be a film bulk acoustic wave resonator (FBAR). In some other embodiments, the cavity 20 can be replaced with a solid acoustic mirror and the BAW device 2 can be a BAW solidly mounted resonator (SMR).

The first electrode 12 can have a relatively high acoustic impedance. The first electrode 12 can include molybdenum (Mo), tungsten (W), ruthenium (Ru), chromium (Cr), iridium (Ir), platinum (Pt), Ir/Pt, or any suitable alloy and/or combination thereof. The second electrode 16 can have a relatively high acoustic impedance. The second electrode 16 can include Mo, W, Ru, Cr, Ir, Pt, Ir/Pt, or any suitable alloy and/or combination thereof. The second electrode 16 can be formed of the same material as the first electrode 12 in certain instances. The thickness of the first electrode 12 can be approximately the same as the thickness of the second electrode 16 in a main acoustically active region of the BAW device 2.

The piezoelectric layer 14 is positioned between the first electrode 12 and the second electrode 16. The piezoelectric layer 14 can include aluminum nitride, zinc oxide, or any other suitable piezoelectric material. The piezoelectric layer 14 can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), or the like. In certain instances, the piezoelectric layer 14 can be an aluminum nitride layer doped with scandium. Doping the piezoelectric layer 14 can adjust resonant frequency. Doping the piezoelectric layer 14 can increase the coupling coefficient k² of the BAW device 2. Doping to increase the coupling coefficient k² can be advantageous at higher frequencies where the coupling coefficient k² can be degraded.

The frequency adjustment layer 18 can include a material that functions as a passivation layer. Therefore, the frequency adjustment layer 18 can be referred to as a passivation and trimming layer, as the frequency adjustment layer 18 can be used for both passivation and frequency trimming or frequency adjustment. The frequency adjustment layer 18 can be a dielectric layer. In some embodiments, the frequency adjustment layer 18 can be a silicon oxycarbide layer, a silicon dioxide layer, or any other suitable passivation layer.

The bonding layer 24 can be in contact with the second electrode 16 and the frequency adjustment layer 18. A bonding strength between the second electrode 16 and the frequency adjustment layer 18 with the bonding layer 24 being greater than a bonding strength between the second electrode 16 and the frequency adjustment layer 18 without the bonding layer 24. In some embodiments, the bonding layer 24 can have a mass density that is less than a mass density of the second electrode 16.

In some embodiments, the bonding layer 24 can include a piezoelectric material. For example, the bonding layer 24 can include the same material as the material of the piezoelectric layer 14. Using the same material for the piezoelectric layer 14 and the bonding layer 24 can be beneficial. For example, the thermal coefficient of expansion of the piezoelectric layer 14 and the bonding layer 24 can be matched. Also, using the same material for the piezoelectric layer 14 and the bonding layer 24 can make the manufacturing process relatively easy by utilizing the existing process used for forming the piezoelectric layer 14. In some embodiments, the bonding layer 24 can include aluminum nitride, zinc oxide, or a doped piezoelectric material. The doped piezoelectric material can be, for example, doped aluminum nitride (e.g., scandium doped aluminum nitride) or doped zinc oxide (e.g., scandium doped zinc oxide). In some embodiments, the bonding layer 24 can include a material of the first electrode 12 when the first electrode 12 and the second electrode 16 have different materials. In some embodiments, the bonding layer 24 can include a material of a layer in the support structure (e.g., a passivation layer). In some embodiments, the bonding layer 24 can include an oxide (e.g., a silicon oxide) or a nitride (e.g., aluminum nitride).

The bonding layer 24 has a thickness t1. The thickness t1 of the bonding layer 24 can be in a range between, for example, 1 nanometer and 20 nanometers, 2 nanometers and 20 nanometers, 3 nanometers and 20 nanometers, 1 nanometer and 10 nanometers, or 3 nanometers and 10 nanometers. When the thickness t1 becomes thicker, performance of the BAW device 2 may be affected by the characteristics of the bonding layer 24. However, in some embodiments, the thickness t1 can be greater than 20 nanometers.

The designs of the first electrode 12, the piezoelectric layer 14, and the second electrode 16 can dominate the performance of a BAW device, and the frequency adjustment layer 18 is provided to fine-tune the BAW device to compensate for, for example, manufacturing variations. Because introducing an additional layer to the BAW device can alter the performance of the BAW device, adding a new layer has been disfavored or unwanted. However, it was discovered that the bonding layer 24 with the thicknesses and the materials disclosed herein does not significantly alter the performance of the BAW device 2 while providing sufficient bonding strength between the second electrode 16 and the frequency adjustment layer 18.

The bonding layer 24 can be beneficial in various BAW device types (e.g., film bulk acoustic resonators, solidly mounted resonators, etc.), that include a frequency adjustment layer 18. In some embodiments, the bonding layer 24 can be compatible with a BAW device with various other features such as a raised frame structure, a recessed frame structure, and a temperature compensation layer.

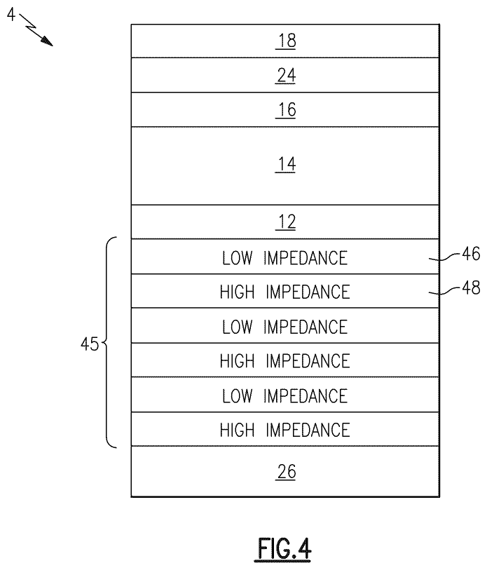

FIG. 3 is a schematic cross-sectional side view of a bulk acoustic wave (BAW) device 3 according to an embodiment. The BAW device 3 can include a support substrate 26, a trap rich layer 28, a passivation layer 30, a cavity 20, a first electrode 12, piezoelectric layer 14, a temperature compensation layer 32, a second electrode 16, a bonding layer 24, and a frequency adjustment layer 18. The BAW device 3 can include a recessed frame structure 34 and a raised frame structure 36. The combination of the support substrate 26, the trap rich layer 28, the passivation layer 30 can be an example of the support structure 10 shown in FIG. 2. Unless otherwise noted, the components of the BAW device 3 shown in FIG. 3 may be structurally and/or functionally the same as or generally similar to like components of the BAW device 2 of FIG. 2.

The support substrate 26 can be a semiconductor substrate, such as a silicon substrate. The support substrate 26 can be a high resistivity silicon substrate. The support substrate 26 can be any other suitable support substrate. The trap rich layer 28 can be a polysilicon layer, an amorphous silicon layer, or the like. The trap rich layer 28 is positioned between the support substrate 26 and the passivation layer 30. The passivation layer 30 can be a buried oxide layer. The passivation layer 30 can be an amorphous silicon oxycarbide layer in certain applications. In some other applications, the passivation layer 30 can be a silicon dioxide layer or any other suitable passivation layer, such as aluminum oxide, silicon carbide, aluminum nitride, silicon nitride, silicon oxynitride, or the like. In some instances, a silicon dioxide layer can be over a trap rich layer and an amorphous silicon oxycarbide layer can be over the silicon dioxide layer.

The temperature compensation layer 32 can bring the TCF of the BAW device 3 closer to zero. The temperature compensation layer 32 can have a positive temperature coefficient of elasticity. The temperature compensation layer 32 can be in physical contact with the piezoelectric layer 14. The temperature compensation layer 32 can include amorphous silicon oxycarbide. As illustrated, the temperature compensation layer 32 can be positioned between the second electrode 16 of the BAW device 3 and the piezoelectric layer 14. Temperature compensated (TC) BAW devices can include an amorphous silicon oxycarbide temperature compensation layer between a piezoelectric layer and upper electrode, between the piezoelectric layer and lower electrode, embedded within a piezoelectric layer, embedded within an electrode, or any suitable combination thereof.

Part of the frequency adjustment layer 18 can form at least part of the recessed frame structure 34 and/or the raised frame structure 36. An active region or active domain of the BAW device 3 can be defined by a portion of the piezoelectric layer 14 that overlaps an acoustic reflector, such as the cavity 20, and is between the first electrode 12 and the second electrode 16. The active region can correspond to where voltage is applied on opposing sides of the piezoelectric layer 14 over the acoustic reflector. The active region can be the acoustically active region of the BAW device 3. The BAW device 3 can include a recessed frame region with the recessed frame structure 34 in the active region and a raised frame region with the raised frame structure 36 in the active region. The main acoustically active region can provide a main mode of the BAW device 3. The main acoustically active region can be the central part of the active region that is free from frame structures, such as the recessed frame structure 34 and the raised frame structure 36.

The bonding layer 24 can be provided at least in the active region. The bonding layer 24 can be provided beyond the active region, in some embodiments. For example, the bonding layer 24 can be provided under an entire lower surface of the frequency adjustment layer 18.

While the BAW device 3 includes the recessed frame structure 34 and the raised frame structure 36, other frame structures can alternatively or additionally be implemented. For example, a raised frame structure with multiple layers including a layer between an electrode of a BAW device and a piezoelectric layer can be implemented. As another example, a floating raised frame structure can be implemented. As one more example, a raised frame structure can be implemented without a recessed frame structure.

One or more metal layers 40 and 42 can connect an electrode of the BAW device 3 to one or more other BAW devices, one or more integrated passive devices, one or more other circuit elements, one or more signal ports, the like, or any suitable combination thereof. An adhesion layer 44 can be positioned between the metal layer 40 and an underlying layer to increase adhesion between the layers. The adhesion layer 44 can be a titanium layer, for example.

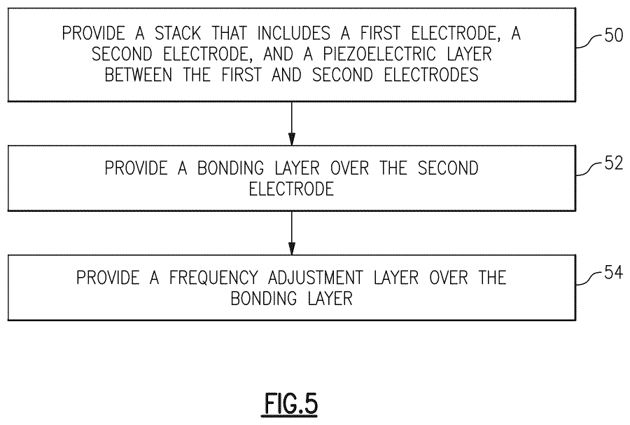

FIG. 4 is a schematic cross-sectional side view of a bulk acoustic wave (BAW) device 4 according to an embodiment. Unless otherwise noted, the components of the BAW device 4 shown in FIG. 4 may be structurally and/or functionally the same as or generally similar to like components of the BAW devices 2, 3 of FIGS. 2 and 3. As illustrated, the bonding layer 24 can be implemented in the BAW device 4.

The bulk acoustic device 4 is a solidly mounted resonator (SMR) instead of an FBAR. In the bulk acoustic wave device 4, a solid acoustic mirror is disposed between the first electrode 12 and the support substrate 26. The illustrated acoustic mirror includes acoustic Bragg reflectors 45. The illustrated acoustic Bragg reflectors 45 include alternating low impedance layers 46 and high impedance layers 48. As an example, the Bragg reflectors 45 can include alternating silicon dioxide layers as low impedance layers 46 and tungsten layers as high impedance layers 48. Any other suitable features of an SMR can alternatively or additionally be implemented in the BAW device 4.

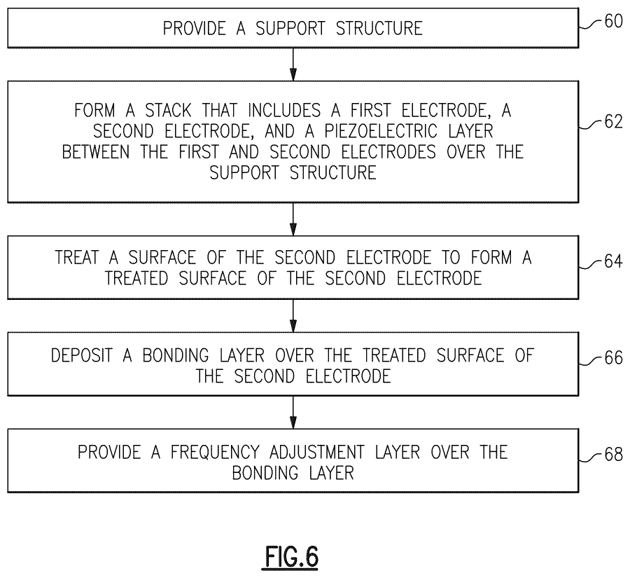

The bonding layer 24 disclosed herein can be provided in a BAW device in any suitable manner. Methods of forming BAW devices that include a bonding layer will be disclosed with respect to FIGS. 5 and 6. The methods may refer to various components shown in FIGS. 2-4.

FIG. 5 is a flow chart showing a method of forming a BAW device according to an embodiment. As shown in block 50, the method can include providing a stack that includes a first electrode 12, a second electrode 16, and a piezoelectric layer 14 between the first and second electrodes 12, 16. As shown in block 52, the method can include providing a bonding layer 24 over the second electrode 16. As shown in block 54, the method can include providing a frequency adjustment layer 18 over the bonding layer 24.

FIG. 6 is a flow chart showing a method of forming a BAW device according to an embodiment. As shown in block 60, the method can include providing a support structure 10. The support structure 10 can include a support substrate (e.g., the support substrate 26), a trap rich layer (e.g., the trap rich layer 28), a passivation layer (e.g., the passivation layer 30), or one or more intermediate layers therebetween. Providing the support structure 10 can include forming such layers over the support substrate.

As shown in block 62, the method can include forming a stack that includes a first electrode 12, a second electrode 16, and a piezoelectric layer 14 between the first and second electrodes 12, 16 over the support structure 10. The first electrode 12, the piezoelectric layer 14, and the second electrode 16 can be formed layer by layer. In some embodiments, there may be one or more additional layers (e.g., the temperature compensation layer 32) formed at one or more locations between the first and second electrodes 12, 16.

As shown in block 64, the method can include treating a surface of the second electrode 16 to form a treated surface of the second electrode 16. Treating the surface of the second electrode 16 can include removing organic matter and oxide from the surface of the second electrode 16. For example, organic matter and oxide can be removed from the surface by way of plasma treatment. In some embodiments, treating the surface of the second electrode 16 can include soft etching or degassing by way of annealing. In some embodiments, the treating process can be referred to as a cleaning process.

As shown in block 66, the method can include depositing a bonding layer 24 over the treated surface of the second electrode 16. In some embodiments, the bonding layer 24 can include sputtering or vapor deposition (e.g., chemical vapor deposition (CVD), atomic layer deposition (ALD), etc.). The bonding layer 24 can have a thickness t1 in a range between, for example, 1 nanometer and 20 nanometers, 2 nanometers and 20 nanometers, 3 nanometers and 20 nanometers, 1 nanometer and 10 nanometers, or 3 nanometers and 10 nanometers.

As shown in block 66, the method can include providing a frequency adjustment layer 18 over the bonding layer 24. The frequency adjustment layer 18 can include a material that functions as a passivation layer. Therefore, the frequency adjustment layer 18 can be referred to as a passivation and trimming layer, as the frequency adjustment layer 18 can be used for both passivation and frequency trimming or frequency adjustment.

The bulk acoustic wave resonators disclosed herein can be implemented in acoustic wave filters. In certain applications, the acoustic wave filters can be band pass filters arranged to pass a radio frequency band and attenuate frequencies outside of the radio frequency band. Two or more acoustic wave filters can be coupled together at a common node and arranged as a multiplexer, such as a duplexer.

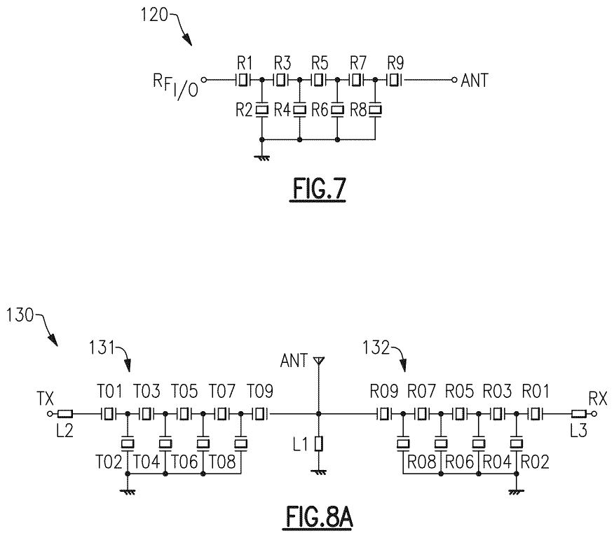

FIG. 7 is a schematic diagram of an example of an acoustic wave ladder filter 120. The acoustic wave ladder filter 120 can be a transmit filter or a receive filter. The acoustic wave ladder filter 120 can be a band pass filter arranged to filter a radio frequency signal. The acoustic wave filter 120 includes series resonators R1, R3, R5, R7, and R9 and shunt resonators R2, R4, R6, and R8 coupled between a radio frequency input/output port RF_{I/O} and an antenna port ANT. The radio frequency input/output port RF_{I/O} can be a transmit port in a transmit filter or a receive port in a receive filter. One or more of the illustrated acoustic wave resonators can be a bulk acoustic wave resonator in accordance with any suitable principles and advantages discussed herein. An acoustic wave ladder filter can include any suitable number of series resonators and any suitable number of shunt resonators.

An acoustic wave filter can be arranged in any other suitable filter topology, such as a lattice topology or a hybrid ladder and lattice topology. A bulk acoustic wave resonator in accordance with any suitable principles and advantages disclosed herein can be implemented in a band pass filter. In some other applications, a bulk acoustic wave resonator in accordance with any suitable principles and advantages disclosed herein can be implemented in a band stop filter.

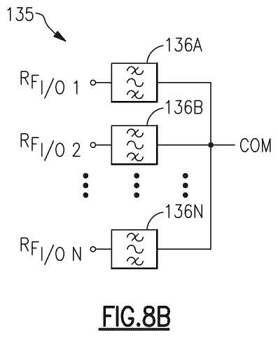

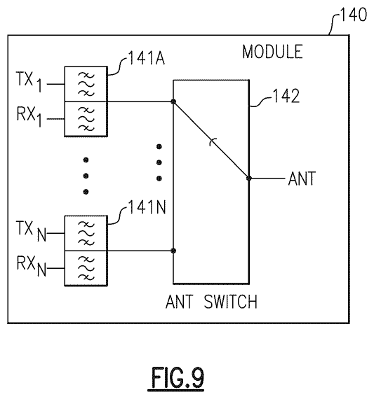

FIG. 8A is a schematic diagram of an example of a duplexer 130. The duplexer 130 includes a transmit filter 131 and a receive filter 132 coupled to each other at an antenna node ANT. A shunt inductor L1 can be connected to the antenna node ANT. The transmit filter 131 and the receive filter 132 are both acoustic wave ladder filters in the duplexer 130.

The transmit filter 131 can filter a radio frequency signal and provide a filtered radio frequency signal to the antenna node ANT. A series inductor L2 can be coupled between a transmit input node TX and the acoustic wave resonators of the transmit filter 131. The illustrated transmit filter 131 includes acoustic wave resonators T01 to T09. One or more of these resonators can be a bulk acoustic wave resonator in accordance with any suitable principles and advantages disclosed herein. The illustrated receive filter includes acoustic wave resonators R01 to R09. One or more of these resonators can be a bulk acoustic wave resonator in accordance with any suitable principles and advantages disclosed herein. The receive filter can filter a radio frequency signal received at the antenna node ANT. A series inductor L3 can be coupled between the resonator and a receive output node RX. The receive output node RX of the receive filter provides a radio frequency receive signal.

FIG. 8B is a schematic diagram of a multiplexer 135 that includes an acoustic wave filter according to an embodiment. The multiplexer 135 includes a plurality of filters 136A to 136N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. Each of the illustrated filters 136A, 136B, and 136N is coupled between the common node COM and a respective input/output node RF_{I/O1}, RF_{I/O2}, and RF_{I/ON}.

In some instances, all filters of the multiplexer 135 can be receive filters. According to some other instances, all filters of the multiplexer 135 can be transmit filters. In various applications, the multiplexer 135 can include one or more transmit filters and one or more receive filters. Accordingly, the multiplexer 135 can include any suitable number of transmit filters and any suitable number of receive filters. Each of the illustrated filters can be band pass filters having different respective pass bands.

The multiplexer 135 is illustrated with hard multiplexing with the filters 136A to 136N having fixed connections to the common node COM. In some other applications, one or more of the filters of a multiplexer can be electrically connected to the common node by a respective switch. Any of such filters can include a bulk acoustic wave resonator according to any suitable principles and advantages disclosed herein.

A first filter 136A is an acoustic wave filter having a first pass band and arranged to filter a radio frequency signal. The first filter 136A can include one or more bulk acoustic wave resonators according to any suitable principles and advantages disclosed herein. A second filter 136B has a second pass band. In certain instances, the common node COM of the multiplexer 135 is arranged to receive a carrier aggregation signal including at least a first carrier associated with the first passband of the first filter 136A and a second carrier associated with the second passband of the second filter 136B.

The bulk acoustic wave resonators disclosed herein can be implemented in a variety of packaged modules. Some example packaged modules will now be discussed in which any suitable principles and advantages of the bulk acoustic wave devices disclosed herein can be implemented. The example packaged modules can include a package that encloses the illustrated circuit elements. The illustrated circuit elements can be disposed on a common packaging substrate. The packaging substrate can be a laminate substrate, for example. FIGS. 9-11 are schematic block diagrams of illustrative packaged modules according to certain embodiments. Certain example packaged modules include one or more radio frequency amplifiers, such as one or more power amplifiers and/or one or more low noise amplifiers. Any suitable combination of features of these modules can be implemented with each other. While duplexers are illustrated in some examples packaged modules, any other suitable multiplexer that includes a plurality of acoustic wave filters coupled to a common node can be implemented instead of one or more duplexers. For example, a quadplexer can be implemented in certain applications. Alternatively or additionally, one or more filters of a packaged module can be arranged as a transmit filter or a receive filter that is not included in a multiplexer.

FIG. 9 is a schematic block diagram of a module 140 that includes duplexers 141A to 141N and an antenna switch 142. One or more filters of the duplexers 141A to 141N can include any suitable number of bulk acoustic wave resonators in accordance with any suitable principles and advantages discussed herein. Any suitable number of duplexers 141A to 141N can be implemented. The antenna switch 142 can have a number of throws corresponding to the number of duplexers 141A to 141N. The antenna switch 142 can electrically couple a selected duplexer to an antenna port of the module 140.

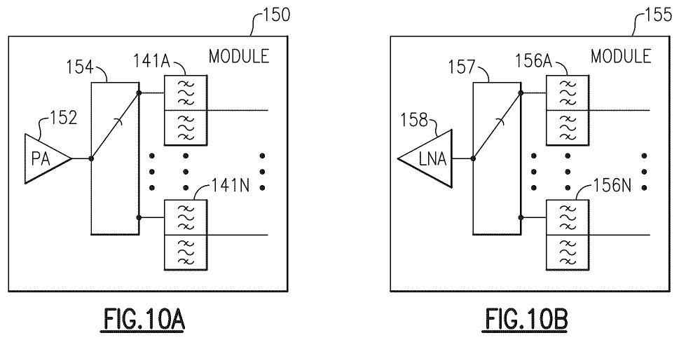

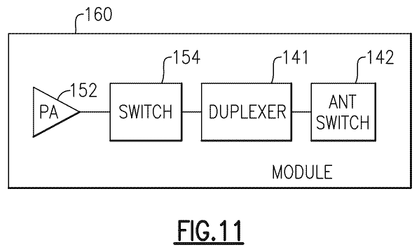

FIG. 10A is a schematic block diagram of a module 150 that includes a power amplifier 152, a radio frequency switch 154, and duplexers 141A to 141N in accordance with one or more embodiments. The power amplifier 152 can amplify a radio frequency signal. The radio frequency switch 154 can be a multi-throw radio frequency switch. The radio frequency switch 154 can electrically couple an output of the power amplifier 152 to a selected transmit filter of the duplexers 141A to 141N. One or more filters of the duplexers 141A to 141N can include any suitable number of bulk acoustic wave resonators in accordance with any suitable principles and advantages discussed herein. Any suitable number of duplexers 141A to 141N can be implemented.

FIG. 10B is a schematic block diagram of a module 155 that includes filters 156A to 156N, a radio frequency switch 157, and a low noise amplifier 158 according to an embodiment. One or more filters of the filters 156A to 156N can include any suitable number of bulk acoustic wave resonators in accordance with any suitable principles and advantages disclosed herein. Any suitable number of filters 156A to 156N can be implemented. The illustrated filters 156A to 156N are receive filters. In some embodiments (not illustrated), one or more of the filters 156A to 156N can be included in a multiplexer that also includes a transmit filter. The radio frequency switch 157 can be a multi-throw radio frequency switch. The radio frequency switch 157 can electrically couple an output of a selected filter of filters 156A to 156N to the low noise amplifier 158. In some embodiments (not illustrated), a plurality of low noise amplifiers can be implemented. The module 155 can include diversity receive features in certain applications.

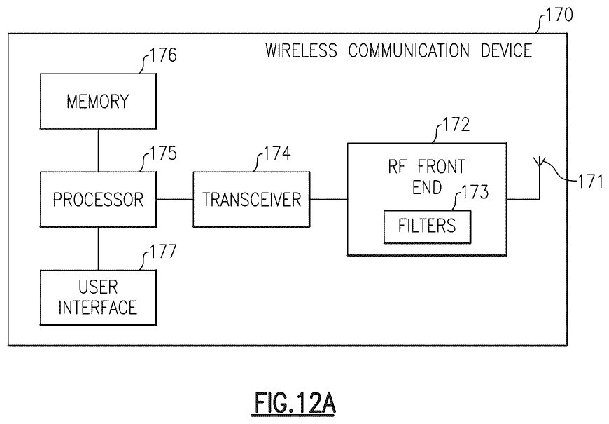

FIG. 11 is a schematic block diagram of a module 160 that includes a power amplifier 152, a radio frequency switch 154, and a duplexer 141 that includes a bulk acoustic wave device in accordance with one or more embodiments, and an antenna switch 142. The module 160 can include elements of the module 140 and elements of the module 150.

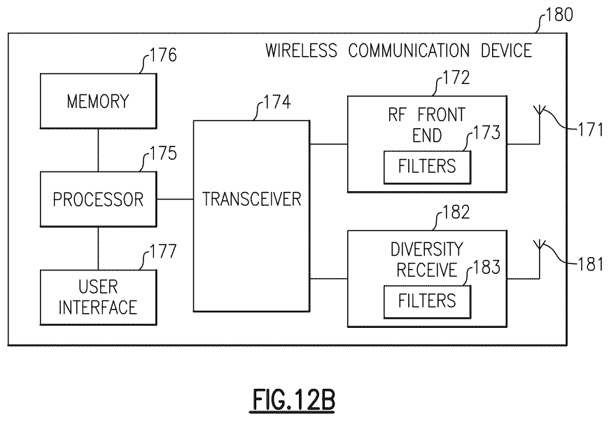

One or more filters with any suitable number of bulk acoustic devices can be implemented in a variety of wireless communication devices. FIG. 12A is a schematic block diagram of a wireless communication device 170 that includes a filter 173 with one or more bulk acoustic wave resonators in accordance with any suitable principles and advantages disclosed herein. The wireless communication device 170 can be any suitable wireless communication device. For instance, a wireless communication device 170 can be a mobile phone, such as a smart phone. As illustrated, the wireless communication device 170 includes an antenna 171, a radio frequency (RF) front end 172 that includes filter 173, an RF transceiver 174, a processor 175, a memory 176, and a user interface 177. The antenna 171 can transmit RF signals provided by the RF front end 172. The antenna 171 can provide received RF signals to the RF front end 172 for processing.

The RF front end 172 can include one or more power amplifiers, one or more low noise amplifiers, RF switches, receive filters, transmit filters, duplex filters, filters of a multiplexer, filters of a diplexers or other frequency multiplexing circuit, or any suitable combination thereof. The RF front end 172 can transmit and receive RF signals associated with any suitable communication standards. Any of the bulk acoustic wave resonators disclosed herein can be implemented in filters 173 of the RF front end 172.

The RF transceiver 174 can provide RF signals to the RF front end 172 for amplification and/or other processing. The RF transceiver 174 can also process an RF signal provided by a low noise amplifier of the RF front end 172. The RF transceiver 174 is in communication with the processor 175. The processor 175 can be a baseband processor. The processor 175 can provide any suitable base band processing functions for the wireless communication device 170. The memory 176 can be accessed by the processor 175. The memory 176 can store any suitable data for the wireless communication device 170. The processor 175 is also in communication with the user interface 177. The user interface 177 can be any suitable user interface, such as a display.

FIG. 12B is a schematic diagram of a wireless communication device 180 that includes filters 173 in a radio frequency front end 172 and second filters 183 in a diversity receive module 182. The wireless communication device 180 is like the wireless communication device 170 of FIG. 12A, except that the wireless communication device 180 also includes diversity receive features. As illustrated in FIG. 12B, the wireless communication device 180 includes a diversity antenna 181, a diversity module 182 configured to process signals received by the diversity antenna 181 and including filters 183, and a transceiver 174 in communication with both the radio frequency front end 172 and the diversity receive module 182. One or more of the second filters 183 can include a bulk acoustic wave resonator with a bonding layer in accordance with any suitable principles and advantages disclosed herein.

Bulk acoustic wave devices disclosed herein can be included in a filter and/or a multiplexer arranged to filter a radio frequency signal in a fifth generation (5G) New Radio (NR) operating band within Frequency Range 1 (FR1). FR1 can from 410 megahertz (MHz) to 7.125 gigahertz (GHz), for example, as specified in a current 5G NR specification. A filter arranged to filter a radio frequency signal in a 5G NR FR1 operating band can include one or more bulk acoustic wave resonators be implemented in accordance with any suitable principles and advantages disclosed herein.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz.

An acoustic wave filter including any suitable combination of features disclosed herein can be arranged to filter a radio frequency signal in a fifth generation (5G) New Radio (NR) operating band within Frequency Range 1 (FR1). A filter arranged to filter a radio frequency signal in a 5G NR operating band can include one or more devices of any of the stacked device arrangements disclosed herein. FR1 can be from 410 MHz to 7.125 GHZ, for example, as specified in a current 5G NR specification. One or more acoustic wave filters in accordance with any suitable principles and advantages disclosed herein can be arranged to filter a radio frequency signal in a fourth generation (4G) Long Term Evolution (LTE) operating band and/or in a filter with a passband that spans a 4G LTE operating band and a 5G NR operating band.

Aspects of this disclosure can be implemented in various electronic devices. Examples of the electronic devices can include, but are not limited to, consumer electronic products, parts of the consumer electronic products such as die and/or acoustic wave components and/or acoustic wave filter assemblies and/or packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a personal digital assistant (PDA), a microwave, a refrigerator, an automobile, a stereo system, a DVD player, a CD player, a digital music player such as an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device comprising:
a piezoelectric layer positioned between a first electrode and a second electrode;
a frequency adjustment layer over the second electrode; and
a bonding layer between the second electrode and the frequency adjustment layer, a bonding strength between the second electrode and the frequency adjustment layer with the bonding layer being greater than a bonding strength between the second electrode and the frequency adjustment layer without the bonding layer.

2. The bulk acoustic wave device of claim 1 wherein the bonding layer has a thickness in a range between 1 nanometer and 20 nanometers.

3. The bulk acoustic wave device of claim 1 wherein the bonding layer includes a piezoelectric material.

4. The bulk acoustic wave device of claim 3 wherein the bonding layer includes aluminum nitride.

5. The bulk acoustic wave device of claim 3 wherein the bonding layer includes a doped piezoelectric material.

6. The bulk acoustic wave device of claim 3 wherein the bonding layer includes scandium doped aluminum nitride or scandium doped zinc oxide.

7. The bulk acoustic wave device of claim 3 wherein the bonding layer includes a material of the piezoelectric layer.

8. The bulk acoustic wave device of claim 1 wherein the second electrode includes ruthenium.

9. The bulk acoustic wave device of claim 1 further comprising a support structure, the first electrode positioned between the support structure and the piezoelectric layer.

10. The bulk acoustic wave device of claim 9 wherein the support structure includes an acoustic mirror.

11. The bulk acoustic wave device of claim 1 wherein a mass density of the bonding layer is less than a mass density of the second electrode.

12. The bulk acoustic wave device of claim 1 wherein the first and second electrodes include the same material.

13. The bulk acoustic wave device of claim 1 wherein the second electrode includes molybdenum (Mo), tungsten (W), ruthenium (Ru), chromium (Cr), iridium (Ir), or platinum (Pt).

14. A bulk acoustic wave device comprising:
a piezoelectric layer positioned between a first electrode and a second electrode;
a bonding layer over the second electrode, the bonding layer having a thickness in a range between 1 nanometer and 20 nanometers; and
a frequency adjustment layer over the bonding layer, the frequency adjustment layer being in contact with the bonding layer.

15. The bulk acoustic wave device of claim 14 wherein the thickness of the bonding layer is in a range between 1 nanometer and 10 nanometers.

16. The bulk acoustic wave device of claim 14 wherein a bonding strength between the second electrode and the frequency adjustment layer with the bonding layer being greater than a bonding strength between the second electrode and the frequency adjustment layer without the bonding layer.

17. The bulk acoustic wave device of claim 14 wherein the bonding layer includes a piezoelectric material.

18. The bulk acoustic wave device of claim 14 wherein the second electrode includes molybdenum (Mo), tungsten (W), ruthenium (Ru), chromium (Cr), iridium (Ir), or platinum (Pt).

19. A method of forming a bulk acoustic wave device, the method comprising:
forming a stack of a first electrode, a second electrode, and a piezoelectric layer positioned between the first electrode and the second electrode;
depositing a bonding layer over the second electrode; and
providing a frequency adjustment layer on the bonding layer, a bonding strength between the second electrode and the frequency adjustment layer with the bonding layer being greater than a bonding strength between the second electrode and the frequency adjustment layer without the bonding layer.

20. The method of claim 19 further comprising removing organic matter and oxide from a surface of the second electrode thereby forming a treated surface, the bonding layer is provided on the treated surface.
